(19) United States
(12) Patent Application Publication
(10) Pub. No.: US 2023/0402294 A1
(43) Pub. Date: Dec. 14, 2023

(54) METHODS FOR MOUNTING AN ELECTRONIC PACKAGE TO A CIRCUIT BOARD

(71) Applicant: Skyworks Solutions, Inc., Irvine, CA (US)

(72) Inventors: Anthony James LoBianco, Irvine, CA (US); Ki Wook Lee, Irvine, CA (US); Yi Liu, San Diego, CA (US)

(21) Appl. No.: 18/329,387

(22) Filed: Jun. 5, 2023

Related U.S. Application Data
(60) Provisional application No. 63/350,602, filed on Jun. 9, 2022.
(60) Provisional application No. 63/350,683, filed on Jun. 9, 2022.
(60) Provisional application No. 63/350,592, filed on Jun. 9, 2022.

(51) Int. Cl. H01L 21/56; H01L 21/60

(52) U.S. Cl. CPC H01L 21/565; H01L 21/60; H01L 2021/6027; H01L 2021/6024

(57) ABSTRACT

Methods are disclosed for mounting an electronic package to a circuit board are disclosed. The electronic package can be mounted to the circuit board by use of intermediate solder portions such that each intermediate solder portion couples a corresponding through-mold connection of the electronic package to the circuit board. The through-mold connections can have a melting point in excess of a melting point of the intermediate solder portions. Related electronic packages, electronic assemblies, electronic devices, and methods of manufacturing electronic packages are disclosed.

### CROSS REFERENCE TO PRIORITY APPLICATIONS

Any and all applications for which a foreign or domestic priority claim is identified in the Application Data Sheet as filed with the present application are hereby incorporated by reference under 37 CFR 1.57. This application claims the benefit of priority of U.S. Provisional Application No. 63/350,592, filed Jun. 9, 2022 and titled “ELECTRONIC PACKAGE, AN ELECTRONIC ASSEMBLY, AN ELECTRONIC DEVICE, A METHOD FOR MANUFACTURING AN ELECTRONIC PACKAGE, AND A METHOD FOR MOUNTING AN ELECTRONIC PACKAGE TO A CIRCUIT BOARD,” U.S. Provisional Application No. 63/350,683, filed Jun. 9, 2022 and titled “ELECTRONIC PACKAGE, AN ELECTRONIC ASSEMBLY, AN ELECTRONIC DEVICE, A METHOD FOR MANUFACTURING AN ELECTRONIC PACKAGE, AND A METHOD FOR MOUNTING AN ELECTRONIC PACKAGE TO A CIRCUIT BOARD,” and U.S. Provisional Application No. 63/350,602, filed Jun. 9, 2022 and titled “ELECTRONIC PACKAGE, AN ELECTRONIC ASSEMBLY, AN ELECTRONIC DEVICE, A METHOD FOR MANUFACTURING AN ELECTRONIC PACKAGE, AND A METHOD FOR MOUNTING AN ELECTRONIC PACKAGE TO A CIRCUIT BOARD,” the disclosures of each of which are hereby incorporated by reference in their entireties and for all purposes.

### BACKGROUND

### Technical Field

The present disclosure relates to an electronic package for mounting to a circuit board. The present disclosure also relates to an electronic assembly including an electronic package mounted to a circuit board. The present disclosure also relates to an electronic device including an electronic assembly, in which the electronic assembly has an electronic package mounted to a circuit board. The present disclosure also relates to a method of manufacturing an electronic package. The present disclosure also relates to a method for mounting an electronic package to a circuit board.

### Description of Related Technology

Conventional electronic packages have a substrate. An array of solder balls is arranged on a first side of the substrate to surround an electronic module mounted to the first side of the substrate. A mold structure is applied over the first side of the substrate to encapsulate the array of solder balls and the electronic module under an outer surface of the mold structure. A grinding or similar operation is subsequently performed on the outer surface of the mold structure to expose the array of solder balls. Laser ablation or a similar process is also performed to locally remove mold material in the vicinity of each of the array of solder balls, to define a moat or channel circumscribing each of the exposed solder balls. The resulting electronic package is coupled to a circuit board by use of portions of solder, each of the solder portions fusing corresponding ones of the exposed solder balls to corresponding mounting locations on the circuit board. The fusing is achieved by a reflow soldering operation in which the package is subject to controlled heat at temperatures sufficient to liquify the solder portions. The high temperatures of the reflow soldering operation also liquifies the array of solder balls. The moat or channel formed by the laser ablation step is provided to permit outgas sing so as to reduce the occurrence of voids at the interface between the array of solder balls and the solder portions.

### SUMMARY OF CERTAIN INVENTIVE ASPECTS

The innovations described in the claims each have several aspects, no single one of which is solely responsible for its desirable attributes. Without limiting the scope of the claims, some prominent features of this disclosure will now be briefly described.

According to one embodiment there is provided an electronic package for mounting to a circuit board, comprising: a substrate having a first side and a second side, the substrate configured to receive one or more electronic modules; a first electronic module mounted to the first side of the substrate; a first mold structure extending over at least part of the first side of the substrate; and a group of electrically conductive through-mold connections provided on the first side of the substrate; the first mold structure substantially encapsulating the group of through-mold connections; the group of through-mold connections exposed through the first mold structure; the group of through-mold connections configured to be coupled to a circuit board by a corresponding group of intermediate solder portions, the through-mold connection configured to have a melting point in excess of a melting point of the intermediate solder portion.

In one example an outer surface of the first mold structure is free of any moat or channel circumscribing and adjacent to each of the through-mold connections.

In one example the through-mold connection is formed of an alloy, the alloy configured to have a solidus temperature greater than a liquidus temperature of the intermediate solder portion.

In one example the through-mold connection is configured to have the melting point of the through-mold connection exceeding the melting point of the intermediate solder portion by at least a predetermined amount, the predetermined amount being 10 degrees Celsius, or 15 degrees Celsius, or 20 degrees Celsius. In one example the through-mold connection is formed of an alloy, the alloy configured to have a solidus temperature exceeding a liquidus temperature of the intermediate solder portion by at least the predetermined amount.

In one example the through-mold connection is formed of a substantially metallic material.

In one example the through-mold connection is formed of a solder material. In one example the solder material is free of lead.

In one example the through-mold connection is formed of an alloy comprising tin and antimony. In one example the alloy comprises 95% by weight of tin and 5% by weight of antimony. In one example the alloy is configured to have a solidus temperature of at least 240 degrees Celsius.

In one example at least one of the group of through-mold connections is coupled to a corresponding electrically conductive node provided on or embedded in the substrate. In one example the electrically conductive node comprises an electrically conductive pad. In one example the through-mold connection is directly fused to the electrically conductive node. In one example the through-mold connection is formed of a substantially metallic material. In one example the through-mold connection is formed of a solder material. In one example the solder material is free of lead. In one example the through-mold connection is formed of an alloy comprising tin and antimony. In one example the alloy comprises 95% by weight of tin and 5% by weight of antimony. In one example the alloy is configured to have a solidus temperature of at least 240 degrees Celsius.

In one example the through-mold connection is formed of a non-solder material. In one example the through-mold connection is predominantly formed of any one of copper, nickel, gold or silver. In one example at least one of the group of through-mold connections is coupled to a corresponding electrically conductive node provided on or embedded in the substrate. In one example at least one of the group of through-mold connections is integrally formed as a single unitary piece with a corresponding electrically conductive node provided on or embedded in the substrate. In one example the group of through-mold connections comprises a group of pillars, each pillar extending away from the first side of the substrate. In one example the group of through-mold connections further comprises a group of first flanges, each first flange disposed on a first end face of a corresponding one of the group of pillars and arranged on the first side of the substrate such that the pillar extends away from the first side of the substrate. In one example corresponding ones of the group of pillars and the group of first flanges are integrally formed as a single unitary piece. In one example the group of through-mold connections further comprises a group of second flanges, each second flange disposed on a second end face of a corresponding one of the group of pillars, the second end face opposite to the first end face, the second flange exposed through the first mold structure. In one example corresponding ones of the group of pillars and the group of second flanges are integrally formed as a single unitary piece.

In one example the electronic package is a dual-sided electronic package.

In one example an end face of at least one of the group of through-mold connections is substantially flush with an outer surface of the first mold structure. In one example the end face of the through-mold connection and the outer surface of the first mold structure together define a planar surface.

In one example the electronic package further comprises the corresponding group of intermediate solder portions, each intermediate solder portion directly fused to an end face of a corresponding one of the group of through-mold connections. In one example the intermediate solder portion is formed of an alloy comprising tin, silver and copper. In one example the alloy comprises 3% by weight of silver and 0.5% by weight of copper. In one example the group of intermediate solder portions protrude above an outer surface of the first mold structure.

In one example the group of through-mold connections substantially surround the first electronic module. In one example the group of through-mold connections comprise a first sub-group of through-mold connections and a second sub-group of through-mold connections, the first sub-group substantially surrounding the second sub-group.

According to another embodiment there is provided an electronic package for mounting to a circuit board, comprising: a substrate having a first side and a second side, the substrate configured to receive one or more electronic modules; a first electronic module mounted to the first side of the substrate; a first mold structure extending over at least part of the first side of the substrate; and a group of electrically conductive through-mold connections provided on the first side of the substrate; the first mold structure substantially encapsulating the group of through-mold connections; the group of through-mold connections exposed through the first mold structure; the group of through-mold connections configured to be coupled to a circuit board by a corresponding group of intermediate solder portions; the group of through-mold connections formed of an alloy comprising tin and antimony, the alloy configured to have a solidus temperature greater than a liquidus temperature of the intermediate solder portion; at least one of the group of through-mold connections directly fused to a corresponding electrically conductive node provided on or embedded in the substrate.

According to another embodiment there is provided an electronic package for mounting to a circuit board, comprising: a substrate having a first side and a second side, the substrate configured to receive one or more electronic modules; a first electronic module mounted to the first side of the substrate; a first mold structure extending over at least part of the first side of the substrate; and a group of electrically conductive through-mold connections provided on the first side of the substrate; the first mold structure substantially encapsulating the group of through-mold connections; the group of through-mold connections exposed through the first mold structure; the group of through-mold connections configured to be coupled to a circuit board by a corresponding group of intermediate solder portions; the group of through-mold connections formed of an alloy comprising tin and antimony, the alloy configured to have a solidus temperature of at least 240 degrees Celsius; at least one of the group of through-mold connections directly fused to a corresponding electrically conductive node provided on or embedded in the substrate.

According to another embodiment there is provided an electronic assembly, comprising: a circuit board configured to receive one or more electronic packages; an electronic package mounted to the circuit board; and a group of intermediate solder portions; the electronic package comprising: a substrate having a first side and a second side, the substrate configured to receive one or more electronic modules; a first electronic module mounted to the first side of the substrate; a first mold structure extending over at least part of the first side of the substrate; and a group of electrically conductive through-mold connections provided on the first side of the substrate; wherein each of the group of intermediate solder portions couple corresponding ones of the group of through-mold connections to the circuit board; the first mold structure substantially encapsulating the group of through-mold connections; the group of through-mold connections exposed through the first mold structure; the group of through-mold connections configured to have a melting point in excess of a melting point of the group of intermediate solder portions.

In one example each intermediate solder portion is directly fused to an end face of a corresponding one of the group of through-mold connections. In one example the end face is substantially flush with an outer surface of the first mold structure.

In one example the group of intermediate solder portions protrude above an outer surface of the first mold structure.

In one example an outer surface of the first mold structure is free of any moat or channel circumscribing and adjacent to each of the through-mold connections.

In one example the through-mold connection is formed of an alloy, the alloy configured to have a solidus temperature greater than a liquidus temperature of the intermediate solder portion.

In one example the through-mold connection is configured to have the melting point of the through-mold connection exceeding the melting point of the intermediate solder portion by at least a predetermined amount, the predetermined amount being 10 degrees Celsius, or 15 degrees Celsius, or 20 degrees Celsius. In one example the through-mold connection is formed of an alloy, the alloy configured to have a solidus temperature exceeding a liquidus temperature of the intermediate solder portion by at least the predetermined amount.

In one example the through-mold connection is formed of a substantially metallic material.

In one example the through-mold connection is formed of a solder material. In one example the solder material is free of lead.

In one example the through-mold connection is formed of an alloy comprising tin and antimony. In one example the alloy comprises 95% by weight of tin and 5% by weight of antimony. In one example the alloy is configured to have a solidus temperature of at least 240 degrees Celsius.

In one example the intermediate solder portion is formed of an alloy comprising tin, silver and copper. In one example the alloy comprises 3% by weight of silver and 0.5% by weight of copper.

In one example at least one of the group of through-mold connections is coupled to a corresponding electrically conductive node provided on or embedded in the substrate. In one example the electrically conductive node comprises an electrically conductive pad. In one example the through-mold connection is directly fused to the electrically conductive node. In one example the through-mold connection is formed of a substantially metallic material. In one example the through-mold connection is formed of a solder material. In one example the solder material is free of lead. In one example the through-mold connection is formed of an alloy comprising tin and antimony. In one example the alloy comprises 95% by weight of tin and 5% by weight of antimony. In one example the alloy is configured to have a solidus temperature of at least 240 degrees Celsius.

In one example the through-mold connection is formed of a non-solder material. In one example the through-mold connection is predominantly formed of any one of copper, nickel, gold or silver. In one example at least one of the group of through-mold connections is coupled to a corresponding electrically conductive node provided on or embedded in the substrate. In one example at least one of the group of through-mold connections is integrally formed as a single unitary piece with a corresponding electrically conductive node provided on or embedded in the substrate. In one example the group of through-mold connections comprises a group of pillars, each pillar extending away from the first side of the substrate. In one example the group of through-mold connections further comprises a group of first flanges, each first flange disposed on a first end face of a corresponding one of the group of pillars and arranged on the first side of the substrate such that the pillar extends away from the first side of the substrate. In one example corresponding ones of the group of pillars and the group of first flanges are integrally formed as a single unitary piece. In one example the group of through-mold connections further comprises a group of second flanges, each second flange disposed on a second end face of a corresponding one of the group of pillars, the second end face opposite to the first end face, the second flange exposed through the first mold structure. In one example corresponding ones of the group of pillars and the group of second flanges are integrally formed as a single unitary piece.

In one example the electronic package is a dual-sided electronic package.

In one example the group of through-mold connections substantially surround the first electronic module. In one example the group of through-mold connections comprise a first sub-group of through-mold connections and a second sub-group of through-mold connections, the first sub-group substantially surrounding the second sub-group.

In one example the electronic assembly forms part of a wireless mobile device.

According to another embodiment there is provided an electronic assembly, comprising: a circuit board configured to receive one or more electronic packages; an electronic package mounted to the circuit board; and a group of intermediate solder portions; the electronic package comprising: a substrate having a first side and a second side, the substrate configured to receive one or more electronic modules; a first electronic module mounted to the first side of the substrate; a first mold structure extending over at least part of the first side of the substrate; and a group of electrically conductive through-mold connections provided on the first side of the substrate; wherein each of the group of intermediate solder portions couple corresponding ones of the group of through-mold connections to the circuit board; the first mold structure substantially encapsulating the group of through-mold connections; the group of through-mold connections exposed through the first mold structure; the group of through-mold connections formed of an alloy comprising tin and antimony, the alloy configured to have a solidus temperature greater than a liquidus temperature of the intermediate solder portion; at least one of the group of through-mold connections directly fused to a corresponding electrically conductive node provided on or embedded in the substrate.

According to another embodiment there is provided an electronic assembly, comprising: a circuit board configured to receive one or more electronic packages; an electronic package mounted to the circuit board; and a group of intermediate solder portions; the electronic package comprising: a substrate having a first side and a second side, the substrate configured to receive one or more electronic modules; a first electronic module mounted to the first side of the substrate; a first mold structure extending over at least part of the first side of the substrate; and a group of electrically conductive through-mold connections provided on the first side of the substrate; wherein each of the group of intermediate solder portions couple corresponding ones of the group of through-mold connections to the circuit board; the first mold structure substantially encapsulating the group of through-mold connections; the group of through-mold connections exposed through the first mold structure; the group of through-mold connections formed of an alloy comprising tin and antimony, the alloy configured to have a solidus temperature of at least 240 degrees Celsius; at least one of the group of through-mold connections directly fused to a corresponding electrically conductive node provided on or embedded in the substrate.

According to another embodiment there is provided an electronic device comprising an electronic assembly, the electronic assembly comprising: a circuit board configured to receive one or more electronic packages; an electronic package mounted to the circuit board; and a group of intermediate solder portions; the electronic package comprising: a substrate having a first side and a second side, the substrate configured to receive one or more electronic modules; a first electronic module mounted to the first side of the substrate; a first mold structure extending over at least part of the first side of the substrate; and a group of electrically conductive through-mold connections provided on the first side of the substrate; wherein each of the group of intermediate solder portions couple corresponding ones of the group of through-mold connections to the circuit board; the first mold structure substantially encapsulating the group of through-mold connections; the group of through-mold connections exposed through the first mold structure; the group of through-mold connections configured to have a melting point in excess of a melting point of the group of intermediate solder portions.

In one example the electronic device is a wireless mobile device.

According to another embodiment there is provided a method for manufacturing an electronic package, the method comprising: providing a substrate having a first side and a second side; arranging a group of electrically conductive through-mold connections on the first side of the substrate, the group of through-mold connections configured to be coupled to a circuit board by a corresponding group of intermediate solder portions, the through-mold connection configured to have a melting point in excess of a melting point of the intermediate solder portion; mounting a first electronic module to the first side of the substrate; applying a first mold structure to the first side of the substrate such that the first mold structure extends over at least part of the first side of the substrate to substantially encapsulate the group of through-mold connections; and removing a portion of the first mold structure to expose the group of through-mold connections.

In one example an outer surface of the first mold structure is kept free of any moat or channel circumscribing and adjacent to each of the through-mold connections.

In one example the step of removing a portion of the first mold structure to expose the group of through-mold connections is such that an outer surface of the first mold structure is kept free of any moat or channel circumscribing and adjacent to each of the through-mold connections.

In one example the through-mold connection is formed of an alloy, the alloy configured to have a solidus temperature greater than a liquidus temperature of the intermediate solder portion.

In one example the through-mold connection is configured to have the melting point of the through-mold connection exceeding the melting point of the intermediate solder portion by at least a predetermined amount, the predetermined amount being 10 degrees Celsius, or 15 degrees Celsius, or 20 degrees Celsius. In one example the through-mold connection is formed of an alloy, the alloy configured to have a solidus temperature exceeding a liquidus temperature of the intermediate solder portion by at least the predetermined amount.

In one example the through-mold connection is formed of a substantially metallic material.

In one example the through-mold connection is formed of a solder material. In one example the solder material is free of lead.

In one example the through-mold connection is formed of an alloy comprising tin and antimony. In one example the alloy comprises 95% by weight of tin and 5% by weight of antimony. In one example the alloy is configured to have a solidus temperature of at least 240 degrees Celsius.

In one example the step of arranging a group of electrically conductive through-mold connections on the first side of the substrate comprises coupling at least one of the group of through-mold connections to a corresponding electrically conductive node provided on or embedded in the substrate. In one example the electrically conductive node comprises an electrically conductive pad. In one example the coupling at least one of the group of through-mold connections to a corresponding electrically-conductive node provided on or embedded in the substrate comprises directly fusing the through-mold connection to the electrically conductive node. In one example the through-mold connection is formed of a substantially metallic material. In one example the through-mold connection is formed of a solder material. In one example the solder material is free of lead. In one example the through-mold connection is formed of an alloy comprising tin and antimony. In one example the alloy comprises 95% by weight of tin and 5% by weight of antimony. In one example the alloy is configured to have a solidus temperature of at least 240 degrees Celsius.

In one example the through-mold connection is formed of a non-solder material. In one example the through-mold connection is predominantly formed of any one of copper, nickel, gold or silver. In one example the step of arranging a group of electrically conductive through-mold connections on the first side of the substrate comprises coupling at least one of the group of through-mold connections to a corresponding electrically conductive node provided on or embedded in the substrate. In one example coupling at least one of the group of through-mold connections to a corresponding electrically conductive node provided on or embedded in the substrate comprises using a solder to form a metallurgical bond between the through-mold connection and the electrically conductive node. In one example the group of through-mold connections comprises a group of pillars, the step of arranging a group of electrically conductive through-mold connections on the first side of the substrate comprising arranging each pillar of the group of pillars to extend away from the first side of the substrate. In one example the step of removing a portion of the first mold structure to expose the group of through-mold connections comprises exposing an end face of the pillar through the first mold structure. In one example the group of through-mold connections further comprises a group of first flanges, each first flange disposed on a first end face of a corresponding one of the group of pillars, the step of arranging a group of electrically conductive through-mold connections on the first side of the substrate comprising arranging each first flange on the first side of the substrate such that the pillar extends away from the first side of the substrate. In one example corresponding ones of the group of pillars and the group of first flanges are integrally formed as a single unitary piece. In one example the group of through-mold connections further comprises a group of second flanges, each second flange disposed on a second end face of a corresponding one of the group of pillars, the second end face opposite to the first end face. In one example the step of removing a portion of the first mold structure to expose the group of through-mold connections comprises exposing the second flange through the first mold structure. In one example corresponding ones of the group of pillars and the group of second flanges are integrally formed as a single unitary piece.

In one example providing a substrate and arranging a group of through-mold connections on the first side of the substrate are combined, such that the substrate is provided in a state in which the group of through-mold connections are pre-arranged on the first side of the substrate.

In one example the step of applying a first mold structure to the first side of the substrate comprises encapsulating at least part of the first electronic module in the first mold structure.

In one example the method further comprises: mounting a second electronic component to the second side of the substrate, and applying a second mold structure to the second side of the substrate such that the second mold structure extends over at least part of the second side of the substrate. In one example the step of applying a second mold structure to the second side of the substrate comprises encapsulating at least part of the second electronic component in the second mold structure.

In one example the step of removing a portion of the first mold structure to expose the group of through-mold connections comprises ablating an outer surface of the first mold structure. In one example the ablating the outer surface of the first mold structure comprises one or more of laser ablating and grinding.

In one example the step of removing a portion of the first mold structure to expose the group of through-mold connections is performed so as to provide an exposed face of each of the group of through-mold connections being substantially flush with an outer surface of the first mold structure. In one example the step of removing a portion of the first mold structure to expose the group of through-mold connections is performed such that the exposed face of each of the group of through-mold connections and the outer surface of the first mold structure collectively define a planar surface.

In one example the method further comprises: providing the corresponding group of intermediate solder portions; and fusing each intermediate solder portion directly to an end face of a corresponding one of the group of through-mold connections. In one example the intermediate solder portion is formed of an alloy comprising tin, silver and copper. In one example the alloy comprises 3% by weight of silver and 0.5% by weight of copper. In one example the step of fusing each intermediate solder portion directly to an end face of a corresponding one of the group of through-mold connections is performed such that each intermediate solder portion protrudes above an outer surface of the first mold structure.

In one example the step of arranging a group of electrically conductive through-mold connections on the first side of the substrate and the step of mounting a first electronic module to the first side of the substrate are performed such that the group of through-mold connections substantially surround the first electronic module. In one example the group of through-mold connections comprise a first sub-group of through-mold connections and a second sub-group of through-mold connections, the first sub-group substantially surrounding the second sub-group.

According to another embodiment there is provided a method for manufacturing an electronic package, the method comprising: providing a substrate having a first side and a second side; arranging a group of electrically conductive through-mold connections on the first side of the substrate, the arranging comprising directly fusing each of the group of through-mold connections to a corresponding electrically conductive node provided on or embedded in the substrate; mounting a first electronic module to the first side of the substrate; applying a first mold structure to the first side of the substrate such that the first mold structure extends over at least part of the first side of the substrate to substantially encapsulate the group of through-mold connections; and removing a portion of the first mold structure to expose the group of through-mold connections; wherein the group of through-mold connections are configured to be coupled to a circuit board by a corresponding group of intermediate solder portions, the through-mold connections formed of an alloy comprising tin and antimony, the alloy configured to have a solidus temperature greater than a liquidus temperature of the intermediate solder portion.

According to another embodiment there is provided a method for manufacturing an electronic package, the method comprising: providing a substrate having a first side and a second side; arranging a group of electrically conductive through-mold connections on the first side of the substrate, the arranging comprising directly fusing each of the group of through-mold connections to a corresponding electrically conductive node provided on or embedded in the substrate; mounting a first electronic module to the first side of the substrate; applying a first mold structure to the first side of the substrate such that the first mold structure extends over at least part of the first side of the substrate to substantially encapsulate the group of through-mold connections; and removing a portion of the first mold structure to expose the group of through-mold connections; wherein the group of through-mold connections are configured to be coupled to a circuit board by a corresponding group of intermediate solder portions, the through-mold connections formed of an alloy comprising tin and antimony, the alloy configured to have a solidus temperature of at least 240 degrees Celsius.

According to another embodiment there is provided a method for mounting an electronic package to a circuit board, the method comprising: providing an electronic package, the electronic package comprising: a substrate having a first side and a second side, the substrate configured to receive one or more electronic modules; a first electronic module mounted to the first side of the substrate; a first mold structure extending over at least part of the first side of the substrate; and a group of electrically conductive through-mold connections provided on the first side of the substrate; the first mold structure substantially encapsulating the group of through-mold connections; the group of through-mold connections exposed through the first mold structure; providing a circuit board configured to receive the electronic package; and mounting the electronic package to the circuit board by use of a group of intermediate solder portions such that each of the group of intermediate solder portions couples corresponding ones of the group of through-mold connections to the circuit board, the through-mold connection configured to have a melting point in excess of a melting point of the intermediate solder portion.

In one example the step of mounting the electronic package to the circuit board comprises fusing each intermediate solder portion directly to an end face of a corresponding one of the group of through-mold connections.

In one example the step of mounting the electronic package to the circuit board comprises performing a reflow operation, the reflow operation configured to reflow each intermediate solder portion directly to an end face of a corresponding one of the through-mold connections. In one example performing the reflow operation comprises applying heat sufficient to liquify the intermediate solder portion in preference to the through-mold connection. In one example performing the reflow operation comprises controlling the application of heat so as to substantially avoid liquification of the through-mold connection during the reflow operation. In one example the reflow operation comprises a preheating phase, a soak phase and a reflow phase, in which performing the reflow operation comprises controlling the application of heat such that liquification of the through-mold connection is confined to a minor portion of the reflow phase. In one example performing the reflow operation comprises controlling the application of heat such that liquification of the through-mold connection occurs for a period of less than 10 seconds, or less than 8 seconds, or less than 6 seconds in the reflow phase. In one example performing the reflow operation comprises controlling the application of heat such that the through-mold connection remains wholly or partially in a solid phase throughout the reflow operation.

In one example an outer surface of the first mold structure is free of any moat or channel circumscribing and adjacent to each of the through-mold connections.

In one example the through-mold connection is formed of an alloy, the alloy configured to have a solidus temperature greater than a liquidus temperature of the intermediate solder portion.

In one example the through-mold connection is configured to have the melting point of the through-mold connection exceeding the melting point of the intermediate solder portion by at least a predetermined amount, the predetermined amount being 10 degrees Celsius, or 15 degrees Celsius, or 20 degrees Celsius. In one example the through-mold connection is formed of an alloy, the alloy configured to have a solidus temperature exceeding a liquidus temperature of the intermediate solder portion by at least the predetermined amount.

In one example the through-mold connection is formed of a substantially metallic material.

In one example the through-mold connection is formed of a solder material. In one example the solder material is free of lead.

In one example the through-mold connection is formed of an alloy comprising tin and antimony. In one example alloy comprises 95% by weight of tin and 5% by weight of antimony. In one example the alloy is configured to have a solidus temperature of at least 240 degrees Celsius.

In one example the through-mold connection is formed of a non-solder material. In one example the through-mold connection is predominantly formed of any one of copper, nickel, gold or silver.

According to another embodiment there is provided a method for mounting an electronic package to a circuit board, the method comprising: providing an electronic package, the electronic package comprising: a substrate having a first side and a second side, the substrate configured to receive one or more electronic modules; a first electronic module mounted to the first side of the substrate; a first mold structure extending over at least part of the first side of the substrate; and a group of electrically conductive through-mold connections provided on the first side of the substrate; the first mold structure substantially encapsulating the group of through-mold connections; the group of through-mold connections exposed through the first mold structure; providing a circuit board configured to receive the electronic package; and mounting the electronic package to the circuit board by use of a group of intermediate solder portions such that each of the group of intermediate solder portions couples corresponding ones of the group of through-mold connections to the circuit board, the through-mold connection formed of an alloy comprising tin and antimony, the alloy configured to have a solidus temperature greater than a liquidus temperature of the intermediate solder portion.

According to another embodiment there is provided a method for mounting an electronic package to a circuit board, the method comprising: providing an electronic package, the electronic package comprising: a substrate having a first side and a second side, the substrate configured to receive one or more electronic modules; a first electronic module mounted to the first side of the substrate; a first mold structure extending over at least part of the first side of the substrate; and a group of electrically conductive through-mold connections provided on the first side of the substrate; the first mold structure substantially encapsulating the group of through-mold connections; the group of through-mold connections exposed through the first mold structure; providing a circuit board configured to receive the electronic package; and mounting the electronic package to the circuit board by use of a group of intermediate solder portions such that each of the group of intermediate solder portions couples corresponding ones of the group of through-mold connections to the circuit board, the through-mold connection formed of an alloy comprising tin and antimony, the alloy configured to have a solidus temperature of at least 240 degrees Celsius.

For purposes of summarizing the disclosure, certain aspects, advantages and novel features of the innovations have been described herein. It is to be understood that not necessarily all such advantages may be achieved in accordance with any particular embodiment. Thus, the innovations may be embodied or carried out in a manner that achieves or optimizes one advantage or group of advantages as taught herein without necessarily achieving other advantages as may be taught or suggested herein.

Still other aspects, embodiments, and advantages of these exemplary aspects and embodiments are discussed in detail below. Embodiments disclosed herein may be combined with other embodiments in any manner consistent with at least one of the principles disclosed herein, and references to “an embodiment”, “some embodiments”, “an alternate embodiment”, “various embodiments”, “one embodiment” or the like are not necessarily mutually exclusive and are intended to indicate that a particular feature, structure, or characteristic described may be included in at least one embodiment. The appearances of such terms herein are not necessarily all referring to the same embodiment.

The present disclosure relates to U.S. patent application Ser. No. ______ [Attorney Docket SKYWRKS.1360A1, titled “ELECTRONIC PACKAGE WITH THROUGH-MOLD CONNECTIONS AND RELATED ELECTRONIC ASSEMBLY,” filed on even date herewith, the entire disclosure of which is hereby incorporated by reference herein. The present disclosure relates to U.S. patent application Ser. No. ______ [Attorney Docket SKYWRKS.1360A2], titled “METHODS FOR MANUFACTURING ELECTRONIC PACKAGES AND ELECTRONIC ASSEMBLIES,” filed on even date herewith, the entire disclosure of which is hereby incorporated by reference herein

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the invention. In the figures, each identical or nearly identical component that is illustrated in various figures is represented by a like numeral. For purposes of clarity, not every component may be labeled in every figure. In the figures:

FIGS. 1A-D are cross-sectional schematic views of a strip of electronic packages according to the background art, at various stages of fabrication of the strip.

FIG. 2 is a cross-sectional schematic view of one of the electronic packages of FIG. 1D when mounted to a circuit board by use of intermediate portions of solder.

FIG. 3 is a cross-sectional schematic view of a first example of an electronic package according to aspects of the present disclosure.

FIG. 4 is a plan schematic view of the electronic package of FIG. 3.

FIG. 5 is a cross-sectional schematic view of the electronic package of FIG. 3 mounted to a circuit board to form an electronic assembly.

FIG. 6 is a detail schematic view of region ‘A’ of FIG. 5.

FIG. 7 is a phase diagram of an example material used for a through-mold connection of the electronic package shown in FIGS. 3 to 6.

FIG. 8 is a graphical representation of the temperature variation over the duration of an example reflow soldering operation used to mount the electronic package of FIG. 3 to the circuit board of FIG. 5.

FIGS. 9A-D are perspective schematic views of alternative examples of through-mold connections.

FIG. 10 is a cross-sectional schematic view of a second example of an electronic package according to aspects of the present disclosure employing through-mold connections generally corresponding to those illustrated in FIG. 9B.

FIG. 11 is a cross-sectional schematic view of the electronic package of FIG. 10 mounted to a circuit board to form an electronic assembly.

FIG. 12 is a detail schematic view of region ‘B’ of FIG. 11.

FIGS. 13A-F illustrate a first example of a method of manufacturing an electronic package according to aspects of the present disclosure.

FIGS. 14A-E illustrate a second example of a method of manufacturing an electronic package according to aspects of the present disclosure.

FIG. 15 illustrates an electronic package having one or more surface mount technology modules mounted on a substrate panel, according to aspects of the present disclosure.

FIG. 16 illustrates a further electronic package having one or more surface mount technology modules mounted on a substrate panel, according to aspects of the present disclosure.

FIG. 17 illustrates a further electronic package having one or more surface mount technology modules mounted on a substrate panel, according to aspects of the present disclosure.

FIG. 18 illustrates an electronic package implemented in a wireless device, according to aspects of the present disclosure.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings. Any suitable principles and advantages of the embodiments disclosed herein can be implemented together with each other. The headings provided herein are for convenience only and are not intended to affect the meaning or scope of the claims.

Aspects and embodiments described herein are directed to an electronic package, preferably a dual-sided electronic package, for mounting to a separate circuit board. In particular, aspects and embodiments described herein allow the electronic package to be mounted to a circuit board by use of intermediate portions of solder coupling through-mold connections of the electronic package to corresponding mounting locations on the circuit board. Aspects and embodiments described herein allow mounting of the electronic package to the circuit board to be achieved with a package design and manufacturing process of reduced complexity, whilst also inhibiting the occurrence of voids or other defects in the vicinity of the interface between the intermediate solder portions and the through-mold connections. Aspects and embodiments described herein potentially allow for reducing the time and cost of manufacturing each individual electronic package.

It is to be appreciated that embodiments of the packages, devices and methods discussed herein are not limited in application to the details of construction and the arrangement of components set forth in the following description or illustrated in the accompanying drawings. The packages, devices and methods are capable of implementation in other embodiments and of being practiced or of being carried out in various ways. Examples of specific implementations are provided herein for illustrative purposes only and are not intended to be limiting. Also, the phraseology and terminology used herein is for the purpose of description and should not be regarded as limiting. The use herein of “including”, “including”, “having”, “containing”, “involving”, and variations thereof is meant to encompass the items listed thereafter and equivalents thereof as well as additional items. References to “or” may be construed as inclusive so that any terms described using “or” may indicate any of a single, more than one, and all of the described terms.

### Electronic Package of the Background Art:

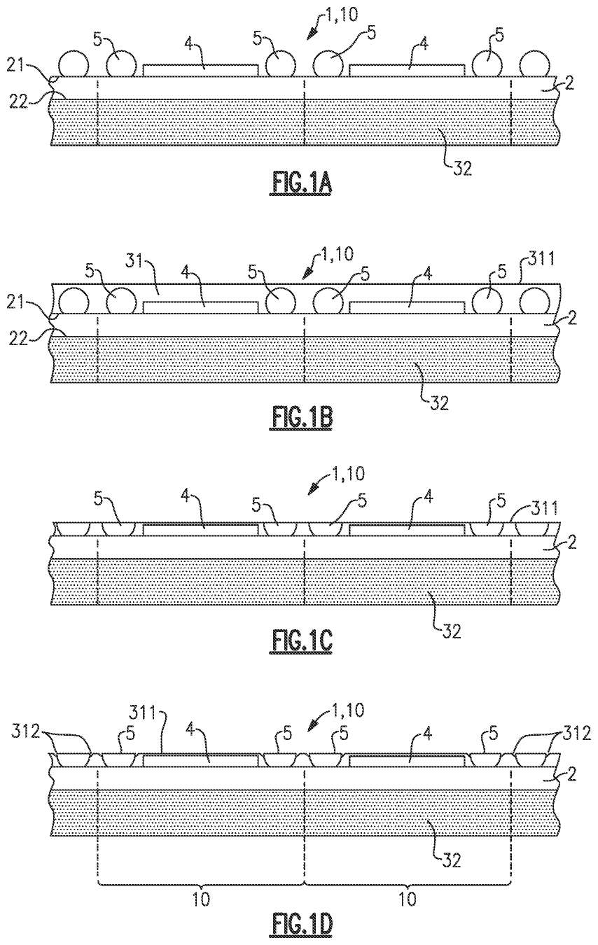

FIGS. 1A-D show a cross-sectional view of a strip 1 of electronic packages 10 of the background art, at various stages of fabrication. The strip 1 contains multiple discrete electronic packages 10. The dashed line in FIGS. 1A-D indicates the boundary between adjacent electronic packages 10 of the strip 1.

FIG. 1A shows a fabrication state in which strip 1 is provided. The strip 1 includes a substrate panel 2 having an upper-facing side 21 and a lower-facing side 22. The upper-facing and lower-facing sides 21, 22 form opposing surfaces of the substrate panel 2. The terms “upper” and “lower” are used here only to indicate the relative disposition of the opposing sides of the substrate panel 2 shown in FIGS. 1A-D; it will be appreciated that during fabrication, the strip 1 may be disposed in orientations different to that shown in FIGS. 1A-D. In an earlier fabrication state (not shown), mold structure 32 is applied over the lower-facing side 22 of the substrate panel 2. For each one of the electronic packages 10, an electronic module 4 is mounted to the upper-facing side 21 of the substrate panel 2. For each one of the electronic packages 10, an array of solder balls 5 is arranged on the upper-facing side 21 of the substrate panel 2. The solder balls 5 are formed of an alloy designated M770 (POR), formed predominantly from tin (Sn) and also including silver (Ag), copper (Cu) and nickel (Ni). The array of solder balls 5 substantially surrounds the electronic module 4. Each of the solder balls 5 is fused by a reflow soldering operation to a corresponding electrically conductive pad (not shown) provided on the substrate panel 2. The electrically conductive pads form part of an electrically conductive pathway of the substrate panel 2 to one or more electronic modules mounted on the substrate panel 2, such as electronic module 4.

FIG. 1B shows a subsequent fabrication state to that illustrated in FIG. 1A. In the fabrication state illustrated in FIG. 1B a mold structure 31 is applied over the upper-facing side 21 of the substrate panel 2 to encapsulate the array of solder balls 5 and the electronic module 4 for each electronic package 10 of the strip 1. The application of the mold structure 31 to the substrate panel 2 results in the solder balls 5 and the electronic module 4 being embedded beneath a planar outer surface 311 of the mold structure 31.

FIG. 1C shows a subsequent fabrication state to that illustrated in FIG. 1B. In the fabrication state illustrated in FIG. 1C, a grinding operation is performed on the planar outer surface 311 of the mold structure 31 to progressively remove material from the mold structure and expose the solder balls 5. The grinding operation also removes some of the material of the solder balls 5. On completion of the grinding operation, the exposed surfaces of the solder balls 5 are flush with the outer surface 311 of the mold structure 31.

FIG. 1D shows a subsequent fabrication state to that illustrated in FIG. 1C. In the fabrication state illustrated in FIG. 1D, a moat or channel 312 is formed around each of the solder balls 5 by ablating material from the mold structure 31. A laser ablation process is used to form each moat or channel 312, with an individual moat/channel 312 being formed around each of the exposed solder balls 5.

In a subsequent fabrication state (not shown), individual ones of the electronic packages 10 are separated from the strip 1 along the dashed lines indicated in FIGS. 1A-1D, thereby defining a discrete electronic package 10.

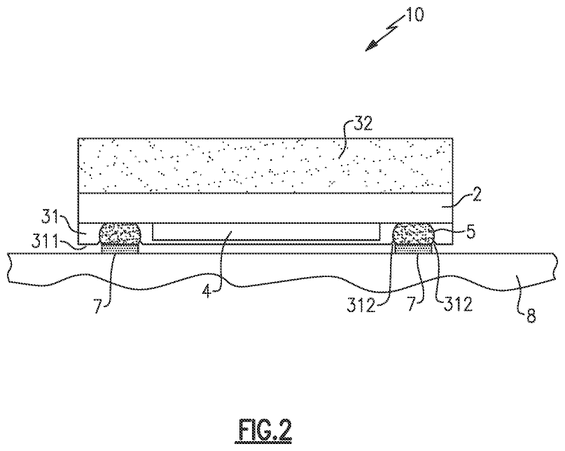

As shown in FIG. 2, each discrete electronic package 10 is subsequently mounted to a circuit board 8 by use of intermediate portions of solder 7. The intermediate portions of solder 7 are formed of an alloy designated SAC 305, formed predominantly from tin (Sn) and also including silver (Ag) and copper (Cu). The composition and physical properties of the solder balls 5 and intermediate solder portions 7 are shown in Table 1 below:

TABLE 1

| | | Properties | |
|---|---|---|---|
| | | M770 (POR) - as | SAC 305 - as used |
| | | used for solder | for intermediate |
| | | balls 5 | solder portions 7 |
| | | Composition | |
| | | Predominantly Sn, | Predominantly Sn, |
| | | plus 2.0% Ag, | plus 3.0% Ag, |
| | | 0.75% Cu, 0.07% Ni | 0.5% Cu |
| Melting Point | Solidus | 218 | 217 |
| (degrees | Liquidus | 224 | 221 |
| Celsius) | | | |

As shown in Table 1, the solidus and liquidus temperatures of the materials used for the solder balls 5 and the intermediate solder portions 7 are similar to each other.

The intermediate solder portions 7 are typically applied to the exposed surfaces of the solder balls 5 as a paste. The electronic package 10 is then aligned relative to the circuit board 8 so that each of the intermediate solder portions 7 mate with a corresponding mounting location on the circuit board. A reflow soldering operation fuses each intermediate solder portion 7 to both: i) a corresponding one of the solder balls 5 of the electronic package and ii) a corresponding mounting location on the circuit board 8. The reflow operation results in liquification of both the solder balls 5 and the intermediate solder portions 7. Consequently, mixing of the liquid phases of the intermediate solder portions 7 and solder balls occurs. The individual moat or channel 312 surrounding each solder ball 5 provides a reservoir for receiving volatile components evolved from the liquified intermediate solder portions 5 and solder balls 5 during the reflow operation. It will be appreciated that incorporation of the moat or channel 312 into the mold structure 31 increases the pitch or spacing between adjacent ones of the solder balls 5. It will also be appreciated that a specific manufacturing operation is involved to form each distinct moat/channel 312 in the mold structure 31.

### Electronic Package and Features Thereof According to Aspects of the Present Disclosure:

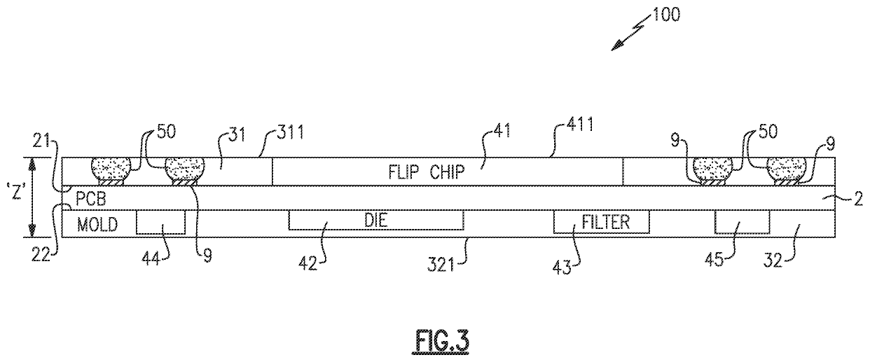

FIG. 3 shows a cross-sectional schematic view of a first example of an electronic package 100 according to aspects of the present disclosure. The electronic package 100 has a substrate panel 2 which is generally planar in form. The substrate panel 2 may have a laminate construction. The substrate panel 2 may include a ceramic substrate. The ceramic substrate may include a low temperature co-fired ceramic substrate. However, it will be appreciated that other materials may be used to form the substrate panel 2. The substrate panel 2 has opposed first and second sides 21, 22.

A flip chip 41 is mounted to the first side 21 of the substrate panel 2 by an arrangement of solder balls (not shown).

A group of through-mold connections 50 substantially surround the flip chip 41. For the example shown in FIG. 3, the through-mold connections 50 are generally spherical in shape and formed of an alloy designated Sn5Sb, the alloy composed predominantly of tin (Sn) and also including antimony (Sb). Properties and characteristics of the Sn5Sb alloy are discussed in subsequent paragraphs of this disclosure. The Sn5Sb alloy is a solder material suitable for fusing with other metallic materials. In certain applications, through-mold connections in embodiments disclosed herein can be formed of any other suitable material, such as a material having a higher melting point than solder connections that connect the through-mold connections to a circuit board such that the through-mold connections do not melt when reflowing the solder connections. Although example materials for solder that connects the through mold connections to a circuit board are described in this disclosured, any other suitable solder materials can alternatively or additionally be used.

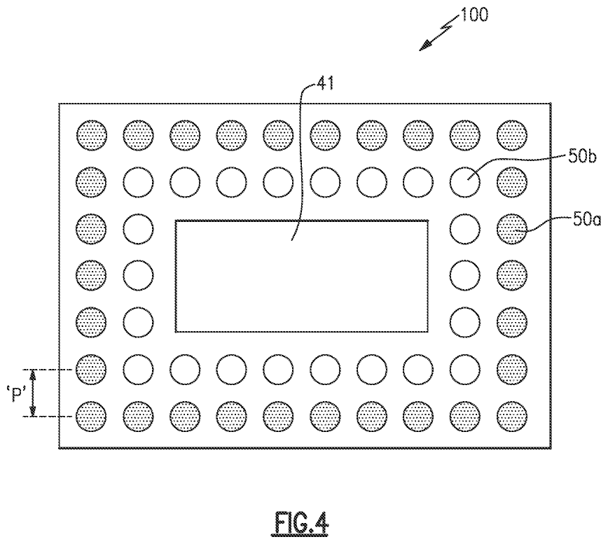

FIG. 4 shows a plan schematic view of the electronic package 100 of FIG. 3. The group of through mold-connections 50 are arranged in a rectangular pattern around the flip chip 41 in first and second sub-groups 50a, 50b. The first sub-group 50a of through-mold connections 50 surrounds the second sub-group 50b of through-mold connections. The rectangular arrangement of first and second sub-groups 50a, 50b of through-mold connections corresponds to the rectangular profile of the flip chip 41. However, it will be appreciated that the profile and area enclosed by the group of through-mold connections 50 may vary according to the size of the electronic module(s) (for example, flip chip 41) enclosed by the group of through-mold connections.

As shown in FIG. 3, a first mold structure 31 extends over the first side 21 of the substrate panel 2. The first mold structure 31 is optionally formed from an epoxy material. However, it will be appreciated that other materials may instead be used to form the first mold structure 31. The first mold structure 31 substantially encapsulates the group of through mold-connections 50, with the through-mold connections 50 exposed through the mold structure 31. Similarly, a surface 411 of the flip chip 41 is also exposed through the mold structure 31. The exposed surfaces of the through-mold connections 50 and the flip chip 41 are flush with the outer surface 311 of the mold structure 31, thereby defining a generally planar surface. In an alternative embodiment (not shown), the flip chip 41 may instead be fully encapsulated by the first mold structure 31 so that the first mold structure extends over the upper surface 411 of the flip chip 41.

For the example shown in FIG. 3, each of the group of through-mold connections 50 is fused to an electrically conductive node defined on or within the substrate panel 2. The electrically conductive node is in the form of an electrically conductive pad 9 provided on the first side 21 of the substrate panel 2. The electrically conductive pads 9 form part of an electrically conductive pathway of the substrate panel 2.

As can be seen in FIG. 3, the outer surface 311 of the first mold structure 31 is free of any moat or channel circumscribing and adjacent to each of the through-mold connections 50. The lack of any such moat or channel may permit closer spacing of adjacent ones of the through-mold connections 50. Adjacent ones of the through-mold connections 50 may have a pitch spacing ‘P’ (also known as ball pitch) (see FIG. 4) of between about 200 micrometers and about 450 micrometers. The electronic package 100 may have a thickness ‘Z’ of less than about 500 micrometers (see FIG. 3).

In the electronic package 100 of FIG. 3, various electronic modules are also mounted to the second side 22 of the substrate panel 2 of the electronic package 1. More particularly, a semiconductor die 42 is mounted to the second side 22 of the substrate panel 2 by use of an array of solder balls (not shown). It will be appreciated that in alternative embodiments other forms of surface mounting technology may be used to mount the semiconductor die 42 to the substrate panel 2, such as wire bonding. A filter 43 and other electronic modules 44, 45 are also mounted to the second side 22 of the substrate panel 2 by any suitable form of surface mounting technology. A second mold structure 32 extends over the second side 22 of the substrate panel 2. In common with the first mold structure 31, the second mold structure 32 is optionally formed from an epoxy material. The semiconductor die 42, filter 43 and other electronic modules 44, 45 are fully encapsulated beneath an outer surface 321 of the second mold structure 32.

The first and second mold structures 31, 32 may help to protect the various electronic modules mounted to the opposing sides 21, 22 of the substrate panel 2 (such as flip chip 41, semiconductor die 42, filter 43) from impact loads encountered during validation testing, transportation or operational use. Impact loads may be dissipated throughout the first and second mold structures 31, 32, thereby helping to reduce the forces encountered by the electronic modules.

The electronic package 100 illustrated in FIG. 3 may be referred to as a dual-sided (DS) package, by virtue of electronic modules (such as flip chip 41, semiconductor die 42, filter 43) being mounted to opposing sides 21, 22 of the substrate panel 2.

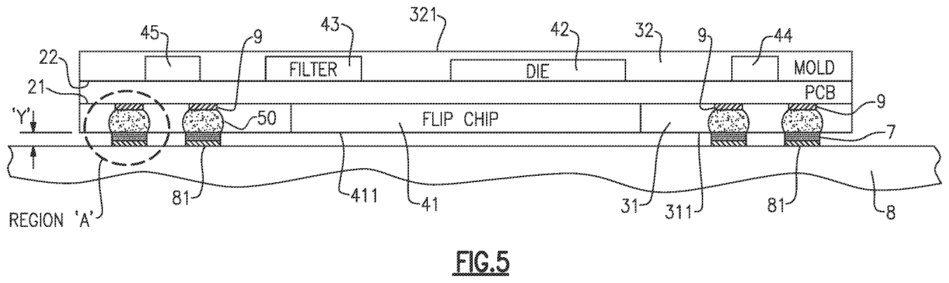

The electronic package 100 of FIG. 3 may subsequently be mounted to a circuit board, such as the circuit board 8 shown in FIG. 5. As discussed in more detail in subsequent paragraphs of this disclosure, the circuit board 8 may itself form part of an electronic device, such as a wireless device. By way of example and without limitation, the wireless device may take the form of a mobile phone, a tablet computer, a smart watch, or a laptop computer.

FIG. 5 shows a cross-sectional view of the electronic package 100 when mounted to circuit board 8. The electronic package 100 is shown inverted relative to the view of FIG. 3. The electronic package 100 is mounted to circuit board 8 by use of intermediate portions of solder 7 extending between the exposed surfaces of the through-mold connections and corresponding mounting locations (in the form of electrically conductive contact pads 81) provided on the circuit board 8. The intermediate portions of solder 7 are formed of a conventional solder alloy, such as SAC 305. Table 2 below illustrates the composition and physical properties of the Sn5Sb alloy used for the through-mold connections 50 and the SAC 305 alloy used for the intermediate solder portions 7:

TABLE 2

| | | Material | |
|---|---|---|---|
| | | Sn5Sb - as | SAC 305 - as |
| | | used for | used for |
| | | through-mold | intermediate solder |
| | | connections 50 | portions 7 |
| Properties | | 95% Sn, plus | Predominantly Sn, |
| Composition | | 5% Sb | plus 3.0% Ag, 0.5% Cu |
| Melting Point | Solidus | 240 | 217 |
| (degrees Celsius) | Liquidus | 243 | 221 |

| | | |
|---|---|---|
| Thermal conductivity | 48.1 | 58 |
| (W/(m K)) | | |

As shown in Table 2, the solidus temperature of the Sn5Sb material used for the through-mold connections 50 exceeds the liquidus temperature of the SAC 305 material used for the intermediate solder portions 7 by a differential or predetermined amount of around 19 degrees Celsius. It will be appreciated that this temperature differential will allow the intermediate solder portions 7 to be reflowed onto the through-mold connections 50 by use of a temperature profile which either avoids any liquification of the material of the through-mold connections 50, or confines any such liquification to those brief periods when the reflow temperature reaches its peak value.

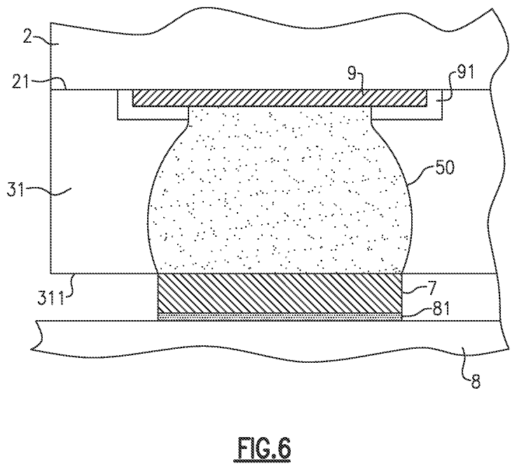

FIG. 6 is a detail schematic view of Region ‘A’ of FIG. 5. FIG. 6 shows electrically conductive pad 9 provided on the first side 21 of the substrate panel 2. Solder mask 91 circumscribes and partially overlaps the electrically conductive contact pad 9. The intermediate solder portion 7 extends between and is fused to both through-mold connection 50 and electrically conductive contact pad 81, thereby physically and electrically connecting the electronic package 100 to the circuit board 8.

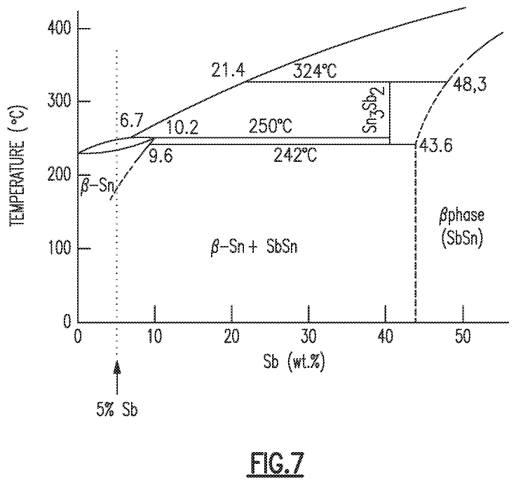

FIG. 7 is a phase diagram of an alloy including tin (Sn) and antimony (Sb), with the abscissa axis representing the weight percentage of antimony in the alloy. The broken line in FIG. 7 at 5% by weight of antimony (Sb) corresponds to the composition of the Sn5Sb material used for the through-mold connections 50 described above for the electronic package 100 of FIGS. 3 to 6.

During the process of mounting the electronic package 100 to the circuit board 8, each of the intermediate solder portions 7 is applied to the exposed surface of corresponding ones of the through-mold connections 50 as a paste. The electronic package 100 is then aligned relative to the circuit board 8 so that each of the intermediate solder portions 7 mate with a corresponding one of the electrically conductive pads 81 on the circuit board. As described in subsequent paragraphs of this disclosure, a reflow soldering operation is performed to fuse each intermediate solder portion 7 to both: i) the corresponding through-mold connection 50 of the electronic package 100 and ii) the corresponding electrically conductive pad 81 of the circuit board 8. The reflow operation is performed at temperatures sufficient to liquify the intermediate solder portions 7 to promote wetting with the material of the through-mold connections 50 and the electrically conductive pads 81.

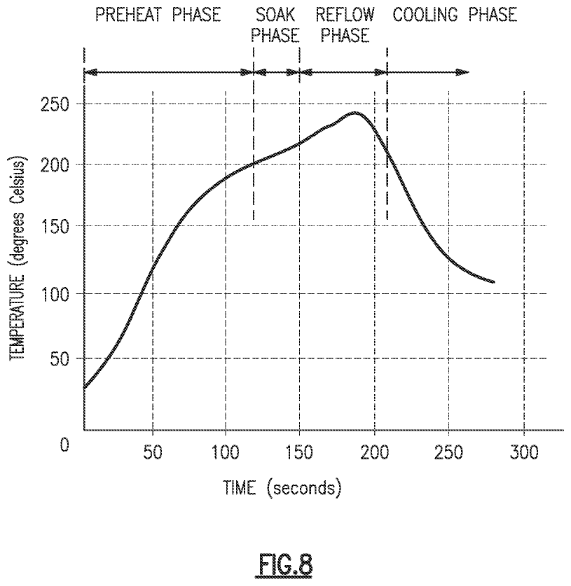

FIG. 8 is a graphical representation of the temperature variation over the duration of an example reflow soldering operation. The reflow soldering operation consists of the following phases: a) a “preheating phase” in which the temperature is progressively increased from ambient temperature to a preheat or soak temperature; b) a “soak phase” in which the temperature is held or allowed to deviate slightly; c) a “reflow phase” in which the temperature is increased above the liquidus temperature of the SAC 305 material used for the intermediate solder portions 7; and d) a “cooling phase” in which the temperature progressively reduces to ambient temperature. Each of these phases is annotated on FIG. 8. For the example reflow soldering operation illustrated in FIG. 8, the temperature is increased to a preheat/soak temperature of around 200 degrees Celsius in the preheating phase, with the temperature then increased slightly from around 200 to around 217 degrees Celsius during the soak phase, with the temperature then increased further during the reflow phase. The example reflow soldering operation illustrated in FIG. 8 has a target peak reflow temperature in the reflow phase of around 240 degrees Celsius, with the reflow phase having a duration of around 60 seconds. In practice, it will be appreciated that the actual peak temperature achieved during the reflow phase may deviate from the 240 degrees Celsius target temperature by a few degrees. The target peak reflow temperature of 240 degrees Celsius corresponds to the solidus temperature for the Sn5Sb alloy employed for the through-mold connections 50. It will of course be appreciated that, in practice, the actual peak reflow temperatures occurring in the reflow phase may differ from the target peak temperature value by a few degrees Celsius. However, even allowing for the actual peak reflow temperature exceeding the target peak reflow temperature by a few degrees, any liquification of the through-mold connections 50 would occur for a very short duration of time, with the peak reflow temperature being maintained only for a matter of seconds. Further, even if the peak reflow temperature were to exceed 240 degrees Celsius, it can be understood from Table 2 that at temperatures between 240 degrees Celsius and 243 degrees Celsius, the through-mold connections 50 would exist as a combination of liquid and solid phases. So, it will be appreciated that any opportunity for mixing of liquid phases of the through-mold connections 50 and the intermediate solder portions 7 is limited, thereby limiting the risk of void formation in the vicinity of the interface between the through-mold connections and intermediate solder portions 7. So, the intermediate solder portions 7 may be reflowed to couple the electronic package 100 to the circuit board 8 without necessitating providing a moat or channel in the first mold structure 31 around each through-mold connection 50. As can be seen in FIGS. 3, 5 and 6, the electronic package 100 is free of the moat or channel 312 employed in the electronic package 10 of the background art of FIGS. 1A-D and 2.

As shown in FIG. 5, the electronic package 100 is mounted to the circuit board 8 to leave a clearance ‘Y’ between the outer surface 311 of the first mold structure 31 and the circuit board 8. The clearance ‘Y’ may help to protect the flip chip 41 from damage due to loads imparted by flexing or dropping. The clearance ‘Y’ may be in a range of around micrometers to 60 micrometers. In alternative embodiments in which the flip chip 41 is fully embedded beneath the outer surface 311 of the mold structure 31, the material of the first mold structure 31 between the outer surface 311 and the outer surface 411 of the flip chip 41 may provide additional protection to the flip chip from loads imparted by flexing or dropping of the electronic package 100. It will be appreciated that the second mold structure 32 encapsulating semiconductor die 42, filter 43 and the other electronic modules 44, 45 may provide similar protection to these components from flexing or dropping.

With the electronic package 100 mounted to the circuit board 8 as shown in FIG. 5, the group of through-mold connections 50 provides an electric conductive pathway between the electronic package 100 and the circuit board 8. Further, the group of through-mold connections 50 may also provide a thermal conductive pathway for passage of heat between the electronic package 100 and the circuit board 8. Table 2 above includes the thermal conductivity of the Sn5Sb alloy used for the through-mold connections 50. Alternative forms of through-mold connections according to aspects of the present disclosure:

For the example electronic package 100 of FIG. 3, the through-mold connections 50 are formed of a fusible alloy intended for use as a solder, in which the through-mold connections are reflowed onto the electrically conductive pads 9 provided on the substrate panel 2. However, in an alternative embodiment, the through-mold connections 50 may be formed of a non-solder material, the non-solder material having a melting point in excess of the melting point of the intermediate solder portions 7. By way of example, in an alternative embodiment the through-mold connections 50 are instead predominantly formed from any one of copper, nickel, silver or gold. Such metals have a melting point far in excess of that of even Sn5Sb, with the melting point of copper, nickel, silver and gold being 1084, 1453, 961 and 1063 degrees Celsius respectively. The elevated melting points of such non-solder materials means the non-solder materials can be thought of as essentially non-reflowable when compared to the intermediate solder portions 7 used to mount the electronic package to the circuit board; more particularly, such non-solder materials do not melt and flow at the temperatures typically used for reflowing the intermediate solder portions 7. FIGS. 9A-D illustrate various examples of different configurations for the through-mold connections 50 when formed of copper.

FIG. 9A illustrates a through-mold connection 50′ resembling an I-section, with first and second flanges 511, 512 disposed on opposed ends of an interconnecting pillar 513. The first and second flanges 511, 512 and interconnecting pillar 513 are integrally formed as a single piece.

FIG. 9B illustrates a through-mold connection 50″ resembling a T-section, with a first flange 511 disposed on one end of pillar 513. The first flange 511 and pillar 513 are integrally formed as a single piece.

FIG. 9C illustrates a through-mold connection 50′″ resembling a cylindrical pillar 513.

FIG. 9D illustrates a copper through-mold connection 50″″ which is generally spheroidal in shape.

It will be appreciated that through-mold connections of non-solder material having profiles different to those illustrated in FIGS. 9A-D may be employed. Further, as discussed above, it will also be appreciated that the through-mold connections 50′, 50″, 50′″, may be formed from electrically conductive, non-solder materials other than copper.

In one embodiment (not shown), the through-mold connections 50′, 50″, 50″″ of FIGS. 9A-D may be coupled to the electrically conductive pads 9 provided on the substrate panel 2 by use of solder, with the solder fusing the through-mold connections to the contact pads. The surface of the through-mold connection 50′, 50″, 50′″, 50″″ exposed through the first mold structure 31 may be plated with a layer of gold (Au), nickel (Ni) or similar metal, and/or an organic surface protection (OSP) layer. The use of such a layer of gold, nickel or similar metal, and/or an organic surface protection layer may help to inhibit oxidation of the exposed surface of the through-mold connection exposed through the first mold structure 31. By way of example, a layer of gold, nickel or similar metal of less than 1 micrometer in thickness may be provided on the exposed surface of the through-mold connection, thereby making a negligible addition to the thickness ‘Z’ of the electronic package.

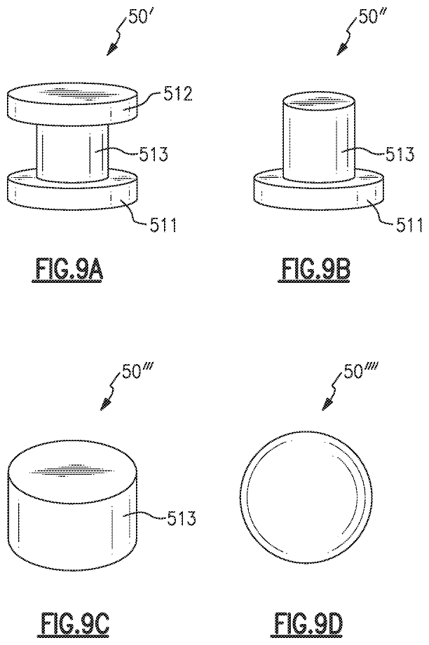

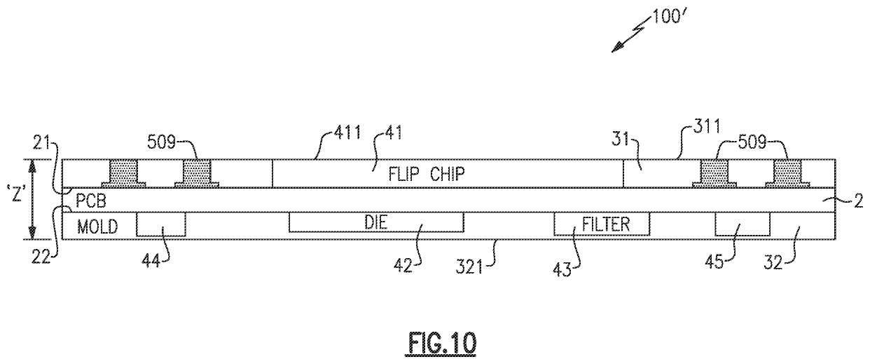

Alternatively, in a preferred embodiment shown in FIG. 10, an electronic package 100′ is provided in which the through-mold connections are integrated with the contact pads as a single unitary piece to form an integrated through-mold connection/contact pad 509 formed of non-solder material, such as copper. The integrated through-mold connection/contact pad 509 avoids the need for a separate soldering operation to couple each through-mold connection to a respective contact pad. By way of example, the integrated through-mold connection/contact pad 509 may be formed by plating directly onto the surface of the substrate panel 2, or onto a copper pad provided on the surface of the substrate panel. In this way, the use of solder to couple the through-mold connection to the substrate panel 2 may be avoided. The plating operation to form the integrated through-mold connection/contact pad 509 may be performed by or on behalf of the manufacturer supplier of the substrate panel 2. As for the embodiment described in the preceding paragraph, the surface of the through-mold connection 50′, 50″, 50′″, 50″″ exposed through the first mold structure 31 may be plated with a layer of gold (Au), nickel (Ni) or similar metal, and/or an organic surface protection (OSP) layer. The use of such a layer of gold, nickel or similar metal, and/or an organic surface protection layer may help to inhibit oxidation of the exposed surface of the through-mold connection exposed through the first mold structure 31. By way of example, a layer of gold, nickel or similar metal of less than 1 micrometer in thickness may be provided, thereby making a negligible addition to the thickness ‘Z’ of the electronic package 100′.

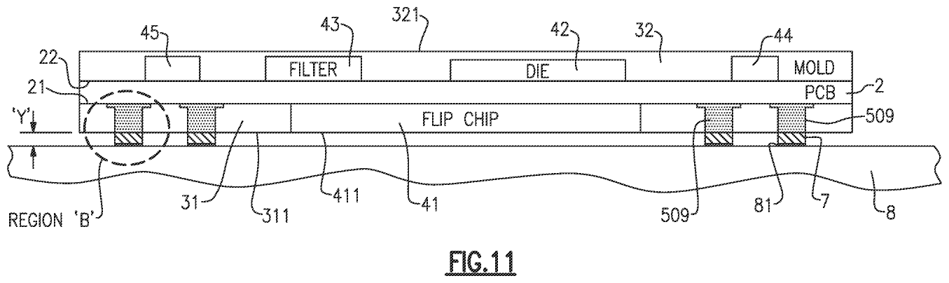

FIG. 11 shows a cross-sectional view of the electronic package 100′ of FIG. when mounted to circuit board 8. In common with the electronic package 100 of FIG. 3, the electronic package 100′ is mounted to circuit board 8 by use of intermediate portions of solder 7. The intermediate portions of solder 7 extend between the exposed surfaces of the integrated through-mold connection/contact pad 509 and corresponding mounting locations (in the form of electrically conductive contact pads 81) of the circuit board 8. The intermediate portions of solder 7 are formed of the conventional SAC 305 solder alloy discussed above. In common with the example embodiment illustrated in FIG. 5, the intermediate solder portions 7 are applied to the exposed surfaces of the through-mold connections 509 as a paste. The electronic package 100′ is then inverted and aligned relative to the circuit board 8 so that each of the intermediate solder portions 7 mate with a corresponding electrically conductive pad 81 of the circuit board. A reflow soldering operation is then performed to fuse each intermediate solder portion 7 to both i) the corresponding integrated through-mold connection/contact pad 509 of the electronic package 100′ and ii) the corresponding electrically conductive contact pad 81 of the circuit board 8. The reflow soldering operation may follow the same temperature/time profile illustrated in FIG. 8. Where the integrated through-mold connection/contact pad 509 is formed of copper, the melting point of copper is far in excess of the target peak reflow temperature for the intermediate solder portions 7. So, the high melting point of copper would ensure that the integrated through-mold connection/contact pads 509 remain in a solid state throughout the reflow soldering operation used to reflow the intermediate solder portions 7.

FIG. 12 is a detail schematic view of Region ‘B’ of FIG. 11. With an integrated through-mold connection/contact pad 509, the solder mask 91 of FIG. 6 can be avoided. By way of example, a photolithography or similar process may be used to form the integrated through-mold connection/contact pads 509 on the substrate panel; this may provide a reduced spacing or pitch between adjacent ones of the through-mold connections. The intermediate solder portion 7 is fused to both the integrated through-mold connection/contact pad 509 and the electrically conductive pad 81, thereby physically and electrically connecting the electronic package 100′ to the circuit board 8.

### Methods for Manufacturing Electronic Packages According to Aspects of the Present Disclosure:

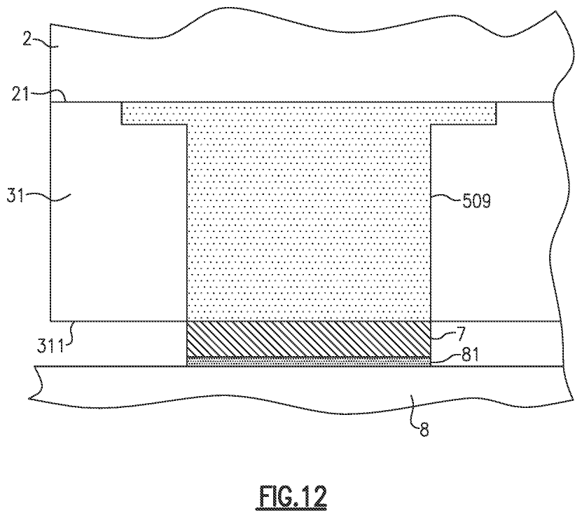

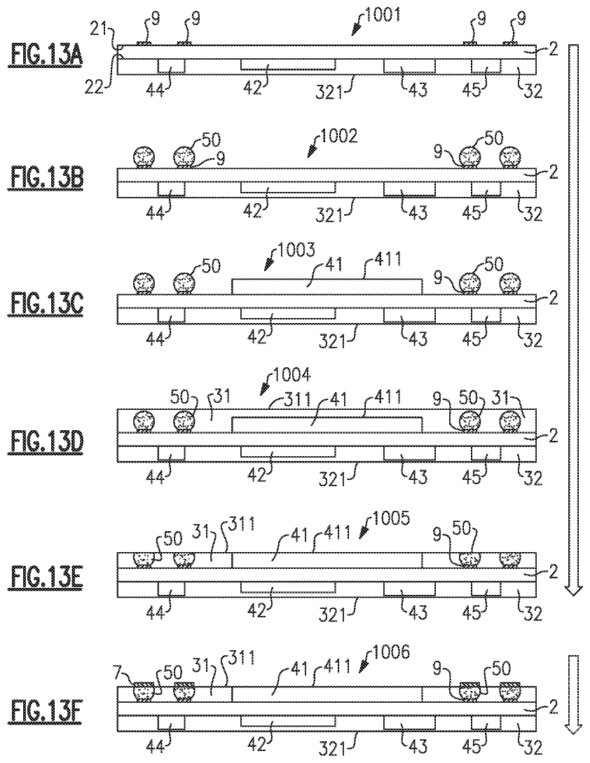

FIGS. 13A-E illustrate examples of fabrication steps 1001, 1002, 1003, 1004, 1005 for use in manufacturing the electronic package 100 of FIG. 3. For the examples shown in these figures, in preceding steps (not shown) electronic modules in the form of semiconductor die 42, filter 43, and other electronic modules 44, 45 are mounted to the second side 22 of the substrate panel 2. The die 42 is mounted by an array of solder balls (not shown), and the filter 43 and other electronic modules 44, 45 mounted by any suitable means of surface mounting technology, such as wire bonding. The second mold structure 32 is applied over the second side 22 of the substrate panel 2 to encapsulate the semiconductor die 42, filter 43 and other electronic modules 44, 45 beneath outer surface 321 of the second mold structure 32. However, it will be appreciated that in other embodiments, the mounting of the semiconductor die 42, filter 43 and other electronic modules 44, 45 to the second side 22 of the substrate panel 2 and the application of the second mold structure 32 may be performed after any one or all of the fabrication steps illustrated in FIGS. 13A-E.

FIG. 13A illustrates a fabrication step 1001 in which the substrate panel 2 is provided. As described in the preceding paragraph, the substrate panel 2 is optionally provided with the semiconductor die 42, filter 43 and other electronic modules 44, 45 having previously been mounted to the substrate panel 2 and encapsulated within the second mold structure 32.

FIG. 13B illustrates a fabrication step 1002 in which the group of through-mold connections 50 are arranged on corresponding electrically conductive contact pads 9 provided on the first side 21 of the substrate panel 2. In the example illustrated in FIG. 13B, the through-mold connections 50 are generally spherical in shape and formed of the Sn5Sb alloy discussed above, the alloy composed predominantly of tin (Sn) and also including antimony (Sb) (see Table 2). The contact pads 9 are formed of copper. A reflow soldering operation is performed to reflow the through-mold connections 50 onto the corresponding contact pads 9, thereby fusing each through-mold connection directly onto a respective contact pad.

FIG. 13C illustrates a fabrication step 1003 in which flip chip 41 is mounted to the first side 21 of the substrate panel 2 by use of an array of solder balls (not shown).

FIG. 13D illustrates a fabrication step 1004 in which first mold structure 31 is applied over the first side 21 of the substrate panel 2 to fully encapsulate the group of through-mold connections 50 and the flip chip 41. In this fabrication step 1004, the outer surface 411 of the flip chip 41 is embedded beneath the outer surface 311 of the first mold structure 31.

FIG. 13E illustrates a fabrication step 1005 in which a portion of the first mold structure 31 is removed by use of a grinding operation or similar to expose both the outer surface 411 of the flip chip 41 and surfaces of the through-mold connections 50. The grinding operation results in removal of some material from the through-mold connections 50. In the illustrated embodiment, the grinding operation is performed so that the outer surface 311 of the first mold structure 31 is flush and co-planar with the exposed surfaces of the flip chip 41 and through-mold connections 50. Completion of this fabrication step 1005 results in the electronic package illustrated in FIG. 13E, which also corresponds to the electronic package 100 shown in FIG. 3.

It will be appreciated that the fabrication step 1003 may precede or be performed substantially simultaneously with fabrication step 1002.

The electronic package 100 resulting from the fabrication steps described in relation to FIGS. 13A-E may be coupled to the circuit board 8 as previously described. The electronic package 100 may be provided to a customer in the state shown in FIG. 13E for subsequent mounting to circuit board 8 by use of intermediate portions of solder 7 formed of conventional SAC 305 material as described above. Alternatively, in an optional additional fabrication step 1006, the discrete intermediate portions of solder 7 may be coupled to each of the exposed surfaces of the through-mold connections 50 prior to shipment of the electronic package 100 to the customer. By way of example, the intermediate portions of solder 7 may be printed onto the exposed surfaces of the through-mold connections 50. On completion of the optional fabrication step 1006, the intermediate portions of solder 7 protrude above the planar outer surface of the first mold structure 31—as shown in FIG. 13F.

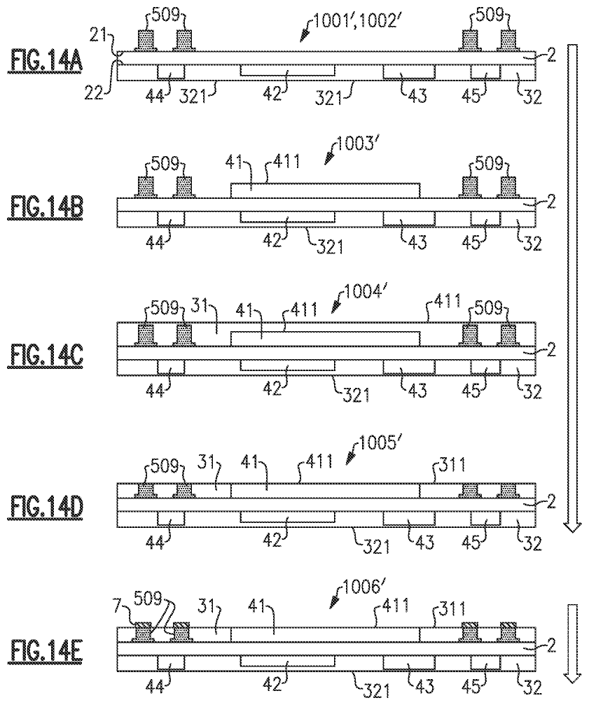

FIGS. 14A-D illustrate examples of fabrication steps 1001′, 1003′, 1004′, 1005′, 1006′ for use in the manufacture of the electronic package 100′ of FIG. 10, in which a group of integrated through-mold connections/contact pads 509 are employed instead of separate through-mold connections 50/contact pads 9. In common with the method illustrated in FIGS. 13A-E, in preceding steps (not shown) electronic modules in the form of semiconductor die 42, filter 43, and other electronic modules 44, 45 are mounted to the second side 22 of the substrate panel 2. The die 42 is mounted by an array of solder balls (not shown), and the filter 43 and other electronic modules 44, 45 mounted by any suitable means of surface mounting technology, such as wire bonding. The second mold structure 32 is applied over the second side 22 of the substrate panel 2 to encapsulate the semiconductor die 42, filter 43 and other electronic modules 44, 45 beneath outer surface 321 of the second mold structure 32. However, it will be appreciated that in other embodiments, the mounting of the semiconductor die 42, filter 43 and other electronic modules 44, 45 to the second side 22 of the substrate panel 2 and the application of the second mold structure 32 may be performed after any one or all of the fabrication steps illustrated in FIGS. 14A-D.

FIG. 14A illustrates a fabrication step 1001′ in which substrate panel 2 is provided with the group of integrated through-mold connections/contact pads 509 in place as part of the structure of the substrate panel. So, the substrate panel 2 is provided in a state in which the group of integrated through-mold connections/contact pads 509 are arranged 1002′ on the first side 21 of the substrate panel 2. The integrated through-mold connections/contact pads 509 may be formed on the substrate panel 2 by an electroplating process or similar in which a copper pillar is progressively plated onto the surface of the substrate panel 2 or a surface of a copper contact pad 9 to form the integrated through-mold connection/contact pad 509. Such an electroplating process or similar may be performed by a manufacturer/supplier of the substrate panel 2.

FIG. 14B illustrates a fabrication step 1003′ in which flip chip 41 is mounted to the first side 21 of the substrate panel 2 by use of an array of solder balls (not shown).

FIG. 14C illustrates a fabrication step 1004′ in which first mold structure 31 is applied over the first side 21 of the substrate panel 2 to fully encapsulate the group of integrated through-mold connections/contact pads 509 and the flip chip 41. In this fabrication step 1004′, the outer surface 411 of the flip chip 41 is embedded beneath the outer surface 311 of the first mold structure 31.

FIG. 14D illustrates a fabrication step 1005′ in which a portion of the first mold structure 31 is removed by use of a grinding operation or similar to expose both the outer surface 411 of the flip chip 41 and surfaces of the integrated through-mold connections/contact pads 509. The grinding operation also results in removal of some material from the integrated through-mold connections/contact pads 509. The grinding operation results in the outer surface 311 of the first mold structure 31 being flush and co-planar with the exposed surfaces of the flip chip 41 and integrated through-mold connections/contact pads 509. Completion of this fabrication step 1005′ results in the electronic package 100′ illustrated in FIG. 14D, which also corresponds to the package shown in FIG. 10. In an additional optional fabrication step performed after completion of step 1005′, a layer of gold, nickel or similar metal may be applied to the exposed surface of each of the integrated through-mold connections/contact pads 509. The layer of gold, nickel or similar metal may be applied by use of an electroplating process or similar. Alternatively, an organic surface protection layer may be applied to the exposed surface of each of the integrated through-mold connections/contact pads 509. The application of such a layer of gold, silver, or similar metal and/or an organic surface protection layer to the exposed surface of the integrated through-mold connection/contact pad 509 may help to inhibit oxidation of the exposed surface of the integrated through-mold connection/contact pad.

The electronic package resulting from the fabrication steps described in relation to FIGS. 14A-D may be mounted to the circuit board 8 as previously described. The electronic package may be provided to a customer in the state shown in FIG. 14D for subsequent mounting to circuit board 8 by use of intermediate portions of solder 7 formed of conventional SAC 305 material as described above. Alternatively, in an optional additional fabrication step 1006′ shown in FIG. 14E, the discrete intermediate portions of solder 7 may be coupled to each of the exposed surfaces of the through-mold connections 50 prior to shipment of the electronic package 100′ to the customer. By way of example, the intermediate portions of solder 7 may be printed onto the exposed surfaces of the through-mold connections 50. On completion of the fabrication step 1006′, the intermediate portions of solder 7 protrude above the planar outer surface of the first mold structure 31.

In other embodiments, a conformal shielding layer (not shown) may be provided to overlie either or both of the first mold structure 31 and the second mold structure 32. The shielding layer may define an electromagnetic interference shield for the electronic package 100, 100′.

### Example Components Mounted to Substrate Panel of Electronic Package According to Aspects of the Present Disclosure:

As will be appreciated, the electronic package 100, 100′ illustrated and described above may employ a variety of different electronic modules mounted to the substrate panel 2. The electronic modules may each be a single discrete electronic component, or alternatively be a collection of two or more electronic components co-located in a common module. It will be appreciated that the examples described herein and illustrated in the figures illustrate non-limiting examples of various electronic modules and that the electronic modules may differ from the specific examples described herein.

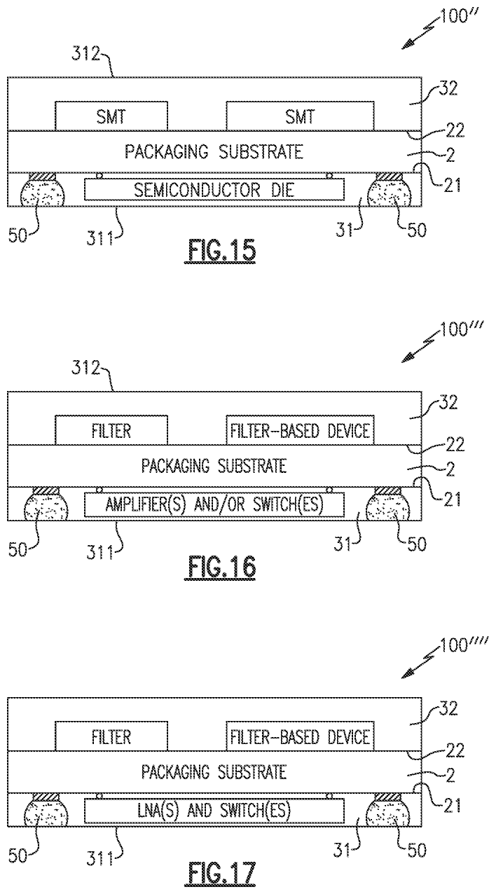

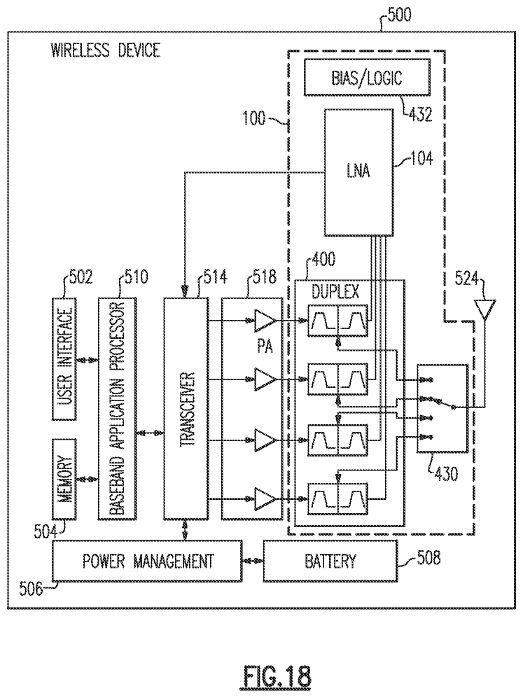

By way of example, FIG. 15 shows an embodiment of a dual-sided electronic package 100″ in which a semiconductor die is mounted to the first side 21 of the substrate panel 2 by an array of solder balls, with other electronic modules mounted to the second side 22 of the substrate panel by any suitable surface mount technology. By way of further example, FIG. 16 shows an embodiment of a dual-sided electronic package 100′″ in which one or more amplifiers and/or switches are mounted to the first side 21 of the substrate panel 2 and a filter/filter-based device mounted to the second side 22 of the substrate panel. In certain applications, the one or more amplifiers and/or switches include one or more power amplifiers and/or one or more low noise amplifiers. By way of further example, FIG. 17 shows an embodiment of a dual-sided electronic package 100′ in which one or more low noise amplifier (LNA) modules and switches are mounted to the first side 21 of the substrate panel 2 and a filter/filter-based device mounted to the second side 22 of the substrate panel.

The electronic packages 100″, 100′″, 100″″ shown in FIGS. 15 to 17 employ through-mold connections 50 generally corresponding to those used in the electronic package 100 of FIG. 3. However, it will be appreciated that in alternative embodiments, the electronic packages 100″, 100′″, 100″″ shown in FIGS. 15 to 17 may employ through-mold connections formed of non-solder material, such as the integrated through-mold connections/contact pads 509 used in the electronic package 100′ of FIG. 10.

### Example Devices Incorporating Electronic Package According to Aspects of the Present Disclosure:

FIG. 18 illustrates an example of how a dual-sided electronic package 100 may be implanted in an electronic device, such as wireless device 500. The wireless device 500 is a wireless communication device. For example, the wireless device 500 can be a mobile phone. In the example wireless device 500 of FIG. 18, the electronic package 100 may be an LNA or LNA-related module—represented by the dashed outline in FIG. 18. By way of example, the LNA module may include one or more LNAs 104, a bias/logic circuit 432, and a band-selection switch 430. Some or all of such circuits can be implemented in a semiconductor die that is mounted on a substrate panel 2 of the LNA module. In such an LNA module, some or all of duplexers 400 can be mounted on the substrate panel 2 so as to form a dual-sided package having one or more features as described herein.

FIG. 18 further depicts various features associated with the example wireless device 500. Although not specifically shown in FIG. 18, the electronic package 100 may instead take the form of a diversity receive (RX) module in place of the LNA module. Alternatively, the electronic package 100 may take the form of a combination of a diversity RX module and an LNA module. It will also be understood that a dual-sided package 100 having one or more features as described herein can be implemented in the wireless device 500 as a non-LNA module.

In the example wireless device 500, a power amplifier (PA) circuit 518 having a plurality of PAs can provide an amplified RF signal to switch 430 (via duplexers 400), and the switch 430 can route the amplified RF signal to an antenna 524. The PA circuit 518 can receive an unamplified RF signal from a transceiver 514 that can be configured and operated in known manners.

The transceiver 514 can also be configured to process received signals. Such received signals can be routed to the LNA 104 from the antenna 524, through the duplexers 400. Various operations of the LNA 104 can be facilitated by the bias/logic circuit 432.

The transceiver 514 is shown to interact with a baseband subsystem 510 that is configured to provide conversion between data and/or voice signals suitable for a user and RF signals suitable for the transceiver 514. The transceiver 514 is also shown to be connected to a power management component 506 that is configured to manage power for the operation of the wireless device 500. Such a power management component can also control operations of the baseband sub-system 510.

The baseband sub-system 510 is shown to be connected to a user interface 502 to facilitate various input and output of voice and/or data provided to and received from the user. The baseband sub-system 510 can also be connected to a memory 504 that is configured to store data and/or instructions to facilitate the operation of the wireless device, and/or to provide storage of information for the user.

A number of other wireless device configurations can utilize one or more features described herein. For example, a wireless device does not need to be a multi-band device. In another example, a wireless device can include additional antennas such as diversity antenna, and additional connectivity features such as Wi-Fi, Bluetooth, and GPS.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes example embodiments, the teachings described herein can be applied to a variety of structures. Any of the principles and advantages discussed herein can be implemented in association with radio frequency (RF) circuits configured to process signals having a frequency in a range from about 30 kHz to 300 GHz, such as in a frequency range from about 400 MHz to 8.5 GHz, in a frequency range from about 410 MHz to 7.125 GHz, or in a frequency range from about 2 GHz to 10 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a vehicular electronics system such as an automotive electronics system, a robot such as an industrial robot, an Internet of things device, a radio, a camera such as a digital camera, a portable memory chip, a kitchen appliance such as a microwave or a refrigerator, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

It will be noted that the figures are for illustrative purposes only, and are not to scale.

Having described above several aspects of at least one embodiment, it is to be appreciated various alterations, modifications, and improvements will readily occur to those skilled in the art. Indeed, the novel electronic packages, electronic assemblies, electronic devices, and methods described herein may be embodied in a variety of other forms. Furthermore, various omissions, substitutions, and changes may be made. Any suitable combination of the elements and/or acts of the various embodiments described above can be combined to provide further embodiments. Such alterations, modifications, and improvements are intended to be part of this disclosure and are intended to be within the scope of the invention. Accordingly, the foregoing description and drawings are by way of example only, and the scope of the invention should be determined from proper construction of the appended claims, and their equivalents.

What is claimed is:

1. A method for mounting an electronic package to a circuit board, the method comprising:
providing an electronic package, the electronic package including a substrate having a first side and a second side, a first electronic module mounted to the first side of the substrate, a first mold structure extending over at least part of the first side of the substrate, and a group of through-mold connections that are electrically conductive and provided on the first side of the substrate, the first mold structure substantially encapsulating the group of through-mold connections, the group of through-mold connections exposed through the first mold structure;
providing a circuit board; and
mounting the electronic package to the circuit board by use of a group of intermediate solder portions such that each intermediate solder portion of the group of intermediate solder portions couples a corresponding through-mold connection of the group of through-mold connections to the circuit board, the through-mold connections having a melting point in excess of a melting point of the intermediate solder portions.

2. The method of claim 1 in which the step of mounting the electronic package to the circuit board comprises fusing each intermediate solder portion directly to an end face of a corresponding one of the group of through-mold connections.

3. The method of claim 1 in which the step of mounting the electronic package to the circuit board comprises performing a reflow operation that reflows each intermediate solder portion directly to an end face of a corresponding one of the through-mold connections.

4. The method of claim 3 in which performing the reflow operation includes applying heat sufficient to liquify the intermediate solder portions in preference to the through-mold connections.

5. The method of claim 4 in which performing the reflow operation includes controlling the application of heat so as to substantially avoid liquification of the through-mold connections during the reflow operation.

6. The method of claim 3 wherein the reflow operation includes a preheating phase, a soak phase, and a reflow phase, in which performing the reflow operation includes controlling the application of heat such that liquification of the through-mold connections is confined to a minor portion of the reflow phase.

7. The method of claim 6 in which performing the reflow operation includes controlling the application of heat such that liquification of the through-mold connections occurs for a period of less than 10 seconds in the reflow phase.

8. The method of claim 3 in which performing the reflow operation comprises controlling the application of heat such that the through-mold connection remains wholly or partially in a solid phase throughout the reflow operation.

9. The method of claim 1 wherein an outer surface of the first mold structure is free of any moat or channel circumscribing and adjacent to each of the through-mold connections.

10. The method of claim 1 wherein the through-mold connections are formed of an alloy, the alloy having a solidus temperature greater than a liquidus temperature of the intermediate solder portions.

11. The method of claim 1 wherein the melting point of the through-mold connections exceeds the melting point of the intermediate solder portions by at least 10 degrees Celsius.

12. The method of claim 1 wherein the through-mold connections are formed of a substantially metallic material.

13. The method of claim 1 wherein the through-mold connections are formed of a solder material.

14. The method of claim 13 wherein the solder material is free of lead.

15. The method of claim 1 wherein the through-mold connection is formed of an alloy including tin and antimony.

16. The method of claim 15 wherein the alloy has a solidus temperature of at least 240 degrees Celsius.

17. The method of claim 1 in which the through-mold connections are formed of a non-solder material.

18. The method of claim 17 in which the through-mold connections are predominantly formed of any one of copper, nickel, gold or silver.

19. A method for mounting an electronic package to a circuit board, the method comprising:
providing an electronic package, the electronic package including a substrate having a first side and a second side, a first electronic module mounted to the first side of the substrate, a first mold structure extending over at least part of the first side of the substrate, and a group of through-mold connections that are electrically conductive and provided on the first side of the substrate, the first mold structure substantially encapsulating the group of through-mold connections, the group of through-mold connections exposed through the first mold structure;
providing a circuit board configured to receive the electronic package; and
mounting the electronic package to the circuit board by use of a group of intermediate solder portions such that each of intermediate solder portion the group of intermediate solder portions couples a corresponding through-mold connection of the group of through-mold connections to the circuit board, the through-mold connections formed of an alloy including tin and antimony, the alloy having a solidus temperature greater than a liquidus temperature of the intermediate solder portions.

20. A method for mounting an electronic package to a circuit board, the method comprising:
providing an electronic package, the electronic package including a substrate having a first side and a second side, a first electronic module mounted to the first side of the substrate, a first mold structure extending over at least part of the first side of the substrate, and a group of through-mold connections that are electrically conductive and provided on the first side of the substrate, the first mold structure substantially encapsulating the group of through-mold connections, the group of through-mold connections exposed through the first mold structure;
providing a circuit board; and
mounting the electronic package to the circuit board by use of a group of intermediate solder portions such that each intermediate solder portion of the group of intermediate solder portions couples a corresponding through-mold connection of the group of through-mold connections to the circuit board, the through-mold connections formed of an alloy including tin and antimony, the alloy having a solidus temperature of at least 240 degrees Celsius.
